(19) United States
(12) Patent Application Publication
(10) Pub. No.: US 2021/0288066 A1
(43) Pub. Date: Sep. 16, 2021

(54) THREE-DIMENSIONAL MEMORY DEVICES HAVING TWO-DIMENSIONAL MATERIALS

(71) Applicant: Yangtze Memory Technologies Co., Ltd., Wuhan (CN)

(72) Inventors: Lifang TAN, Wuhan (CN); Feng Gao, Wuhan (CN)

(73) Assignee: Yangtze Memory Technologies Co., Ltd., Wuhan (CN)

(21) Appl. No.: 17/016,778

(22) Filed: Sep. 10, 2020

Related U.S. Application Data
(63) Continuation of application No. PCT/CN2020/078722, filed on Mar. 11, 2020.

(51) Int. Cl. H01L 27/11582

(52) U.S. Cl. CPC H01L 27/11582

(57) ABSTRACT

Methods and structures of a three-dimensional memory device are disclosed. A 3D NAND memory structure includes a substrate and a vertical insulating layer. The 3D NAND memory structure also includes a channel layer surrounding the vertical insulating layer. The channel layer is formed of a two-dimensional material. The 3D NAND memory structure further includes a plurality of vertical dielectric layers surrounding the channel layer and an alternating conductor/dielectric stack in contact with the plurality of vertical dielectric layers.

### CROSS-REFERENCE TO RELATED APPLICATIONS

This application claims priority to PCT Patent Application No. PCT/CN2020/078722, filed on Mar. 11, 2020, which is incorporated herein by reference in its entirety.

### TECHNICAL FIELD

The present disclosure generally relates to the field of semiconductor technology, and more particularly, to a method for forming a three-dimensional (3D) memory device.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 illustrates a three-dimensional view of a memory device, in accordance with some embodiments of the present disclosure.

FIGS. 2-4 are cross-sectional views of a memory device adopting two-dimensional materials, in accordance with some embodiments of the present disclosure.

FIG. 5 illustrates an exemplary fabrication process for forming a three-dimensional memory structure, in accordance with some embodiments of the present disclosure.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context.

For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate comprises a top surface and a bottom surface. The top surface of the substrate is where a semiconductor device is formed, and therefore the semiconductor device is formed at a top side of the substrate. The bottom surface is opposite to the top surface and therefore a bottom side of the substrate is opposite to the top side of the substrate .The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

As used herein, the term “ring-shaped layer” refers to a layer that forms a close loop such that an end of the layer is connected to an other end of the layer. A ring-shaped layer has an inner surface and an outer surface opposite to the inner surface. The inner surface, facing inward of the ring-shaped layer, is separated from the outer surface, facing outward of the ring-shaped layer, by a thickness of the ring-shaped layer.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D NAND memory device” (referred to herein as “memory device”) refers to a semiconductor device with vertically-oriented strings of 3D NAND memory cell transistors (referred to herein as “memory strings,” such as NAND strings or 3D NAND strings) on a laterally-oriented substrate so that the memory strings extend in the vertical direction with respect to the substrate. As used herein, the term “vertical/vertically” means nominally perpendicular to the lateral surface of a substrate.

In the present disclosure, the term “horizontal/horizontally” means nominally parallel to the lateral surface of a substrate.

In the present disclosure, for ease of description, “tier” is used to refer to elements of substantially the same height along the vertical direction. For example, a word line and the underlying gate dielectric layer can be referred to as “a tier,” a word line and the underlying insulating layer can together be referred to as “a tier,” word lines of substantially the same height can be referred to as “a tier of word lines” or similar, and so on.

As the demand for higher storage capacity continues to increase, the number of vertical levels of the memory cells and staircase structures also increases. For example, a 64-level 3D NAND memory device can include two 32-level staircase structures with one formed on top of the other. Similarly, a 128-level 3D NAND memory device can include two 64-level staircase structures. As device critical dimensions continue to shrink, it is increasingly more challenging to maintain high current density in channel structures of the 3D NAND memory devices. Channels incorporating polysilicon material may have disadvantages such as low carrier mobility and low current density, and may not meet the high drive current demand of memory devices with higher storage capacity.

Embodiments of 3D NAND memory device and fabrication methods are described in the present disclosure. 3D NAND memory cells incorporating two-dimensional material as the channel material can provide improved carrier mobility which in turn improves the channel current density. In general, two-dimensional materials can refer to a material that is a few nanometers or less. Semiconductor material rely on charge carriers such as electrons or holes to conduct electricity. In a two-dimensional material, charge carriers are free to move in a two-dimensional plane and are largely restricted to move in a third direction that is perpendicular to the two-dimensional plane. In some embodiments, the two-dimensional material can include molybdenum disulfide, tungsten disulfide, molybdenum diselenide, any suitable two-dimensional material, and/or combinations thereof. In contrast to the zero band gap structure of pristine graphene material, molybdenum disulfide is a direct band gap semiconductor and when utilized as the channel for 3D NAND memory devices can improve the channel current density. In some embodiments, thickness of the two-dimensional material that is used to form the channel layer can be adjusted according to device needs. For example, the thickness of the channel layer can be more than a few monolayers while retaining high carrier mobility.

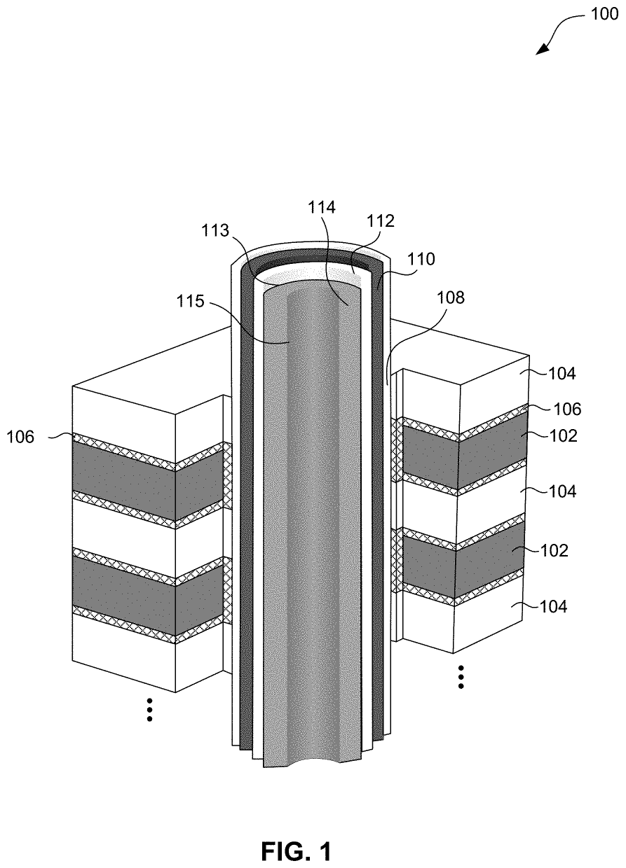

FIG. 1 illustrates a 3D view of a portion of memory device 100. Memory device 100 shown in FIG. 1 is an enlarged view of a portion of a 3D NAND memory device, and memory device 100 can include other structures not shown in FIG. 1 for simplicity. For example, memory device 100 can include a substrate, insulating layers, semiconductor plugs, interconnect structures, liner layers, barrier layers, protective layers, and any other suitable structures. Memory device 100 can include a vertical memory string and a horizontal alternating stack of word line 102 and insulating layer 104. Word lines 102 and insulating layers 104 are shown in FIG. 1 for illustrative purposes, and memory device 100 can further include any suitable numbers of word lines 102 and insulating layers 104. Memory device 100 can be formed over a substrate (not shown in FIG. 1). The memory string can include blocking layer 108, charge-trapping layer 110, tunneling layer 112, and channel layer 114. In some embodiments, a high-k (e.g., dielectric constant greater than about 3.9) blocking layer 106 can be formed between word line 102 and insulating layer 104 and/or between word line 102 and blocking layer 108. The memory string extends substantially through tiers of alternating word line 102 and insulating layer 104. Memory device 100 can include suitable number of tiers of alternating word lines and insulating layers. For example, memory device 100 can include 16 tiers, 32 tiers, 64 tiers, 128 tiers, or any suitable number of tiers. Each intersection of a tier of word line and the memory string forms a memory cell (referred to herein as “memory cell”). In some embodiments, a plurality of memory cells are formed in series along a memory string. An ON or OFF state of a current along an intersected portion of semiconductor layer 104 represents the data stored in the memory cell. The ON or OFF state of a memory cell is determined by a threshold voltage of the memory cell. Threshold voltages can be controlled by trapped charges stored in an intersected portion of charge-trapping layer 110 and affected by a bias voltage applied at the corresponding word line.

Channel layer 114 can be a ring-shaped layer with an outer surface 113 and an inner surface 115. According to some embodiments of the present disclosure, channel layer 114 can be formed using two-dimension material or materials that exhibits similar carrier mobility as two dimension materials to provide high carrier mobility. In some embodiments, channel layer 114 can be formed using molybdenum disulfide. In some embodiments, channel layer 114 can be a monolayer or include a few layers of monolayers. Tunneling layer 112 is a ring-shaped layer surrounding channel layer 114 where an inner surface of tunneling layer 112 is in contact with outer surface 113 of channel layer 114. Similarly, charge-trapping layer 110 is a ring-shaped layer surrounding tunneling layer 112 and blocking layer 108 is a ring-shaped layer surrounding charge-trapping layer 110. A portion of an outer surface of blocking layer 108 is in contact with word line 102. In some embodiments, a high-k blocking layer 106 is disposed between word line 102 and blocking layer 108.

In some embodiments, the substrate can include any suitable material for forming the three-dimensional memory device. For example, the substrate can include silicon, silicon germanium, silicon carbide, silicon on insulator (SOI), germanium on insulator (GOI), glass, gallium nitride, gallium arsenide, III-V compound, glass, plastic sheet, any other suitable materials, and/or combinations thereof.

In some embodiments, tunneling layer 112 can include silicon oxide, silicon nitride, any suitable materials, and/or combinations thereof. In some embodiments, blocking layer 108 can include, but not limit to, silicon oxide, silicon nitride, high-k dielectrics, or any combinations thereof. In some embodiments, charge-trapping layer 110 can include, but not limit to, silicon nitride, silicon oxynitride, and/or combinations thereof. In some embodiments, high-k blocking layer 106 can include, but not limit to, aluminum oxide (Al₂O₃), hafnium oxide (HfO₂), tantalum oxide (Ta₂O₅), any suitable materials, and/or combinations thereof. In some embodiments, word line 102 can include, but not limit to, tungsten (W), cobalt (Co), copper (Cu), aluminum (Al), doped silicon, silicides, titanium nitride (TiN), tantalum nitride (TaN), any suitable materials, and/or combinations thereof In some embodiments, insulating layer 104 can include, but not limit to, silicon oxide, silicon nitride, any suitable materials, and/or combinations thereof.

In some embodiments, insulating layer 104, blocking layer 108, charge-trapping layer 110, and tunneling layer 112 can be formed using deposition techniques including, but not limiting to, CVD, plasma-enhanced CVD (PECVD), low pressure CVD (LPCVD), physical vapor deposition (PVD), high density plasma (HDP), ALD, any suitable deposition techniques, and/or combinations thereof. In some embodiments, word line 102 can be formed using deposition techniques including, but not limiting to, CVD, ALD, sputtering, metal-organic chemical vapor phase deposition (MOCVD), any suitable deposition techniques, and/or combinations thereof

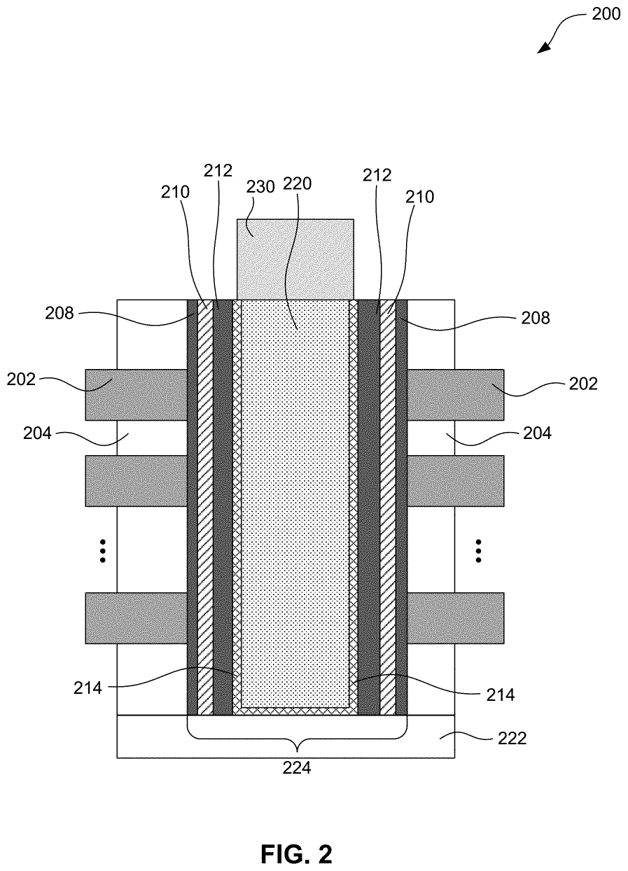

FIG. 2 illustrates a cross-sectional view of memory device 200 incorporating two-dimensional material in a 3D NAND memory cell structure. A two-dimensional material (also known as 2D material) is a type of material with thicknesses on the atomic scale (e.g., one or a few monolayers thick). In a two-dimensional material, charge carriers are free to move in a two-dimensional plane and are largely restricted to move in a third direction that is perpendicular to the two-dimensional plane.

Memory device 200 includes substrate region 222 of a substrate, an alternating stack of word line 202 and insulating layer 204 formed over substrate region 222, and hole 224 extending vertically through the alternating stack. Hole 224 can be filled with blocking layer 208, charge-trapping layer 210, tunneling layer 212, a channel layer 214, and insulating layer 220. In some embodiments, word line 202, insulating layer 204, blocking layer 208, charge-trapping layer 210, tunneling layer 212 can be made of similar materials as word line 102, insulating layer 104, blocking layer 108, charge-trapping layer 110, and tunneling layer 112, respectively. In some embodiments, the materials can respectively be different. Blocking layer 208 can be in contact with substrate region 222 and sidewalls of hole 224, and charge-trapping layer 210 can be formed in physical contact with blocking layer 208. Tunneling layer 212 is in between charge-trapping layer 210 and channel layer 214. In some embodiments, an additional insulating layer 220 is disposed to contact inner surfaces of channel layer 214. In some embodiments, a portion of outer surfaces of blocking layer 208 is in contact with word line 202. In some embodiments, semiconductor plug 230 is disposed over channel layer 214 and forms a contact to a bit line.

Channel layer 214 can be formed using two-dimensional material to enhance the carrier mobility in the channel structure of the 3D NAND memory device. In some embodiments, channel layer 214 can be formed of molybdenum disulfide, tungsten disulfide, molybdenum diselenide, any suitable two-dimensional material, and/or combinations thereof. In some embodiments, channel layer 214 can be formed using any suitable material that has direct band gap that can provide improved carrier mobility. Channel layer 214 can be formed using any suitable deposition method, such as chemical vapor deposition (CVD). In some embodiments, channel layer 214 can be formed using atomic layer deposition (ALD), physical vapor deposition (PVD), any suitable deposition methods, and/or combinations thereof

In some embodiments, semiconductor plug 230 can be formed in physical contact with the inner surfaces of channel layer 214. Semiconductor plug 230 can be formed of amorphous silicon, amorphous silicon-germanium, amorphous silicon carbide, polycrystalline silicon, polycrystalline silicon-germanium, polycrystalline silicon carbide, any suitable semiconductor material, and/or combinations thereof. Semiconductor plug 230 can be used as a contact for a bit line.

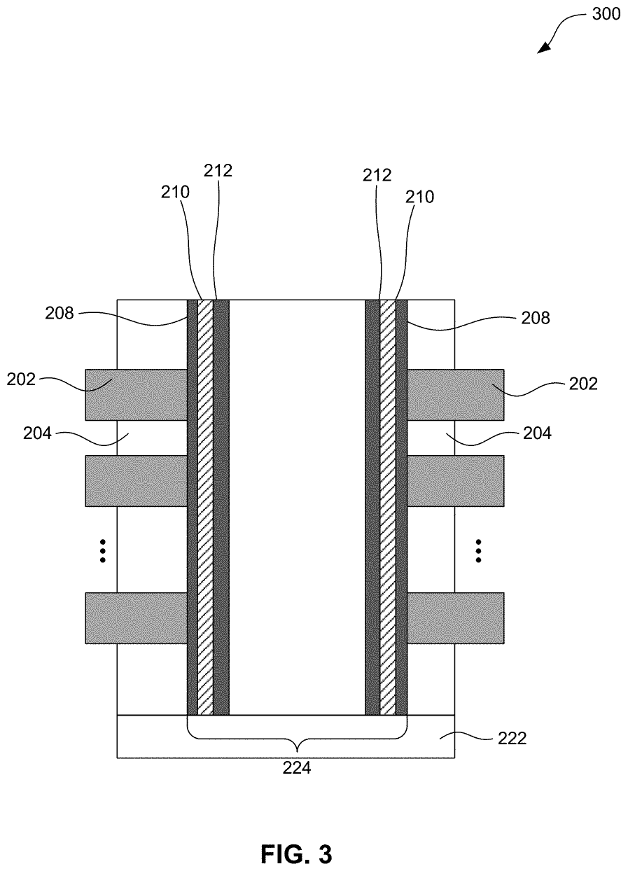

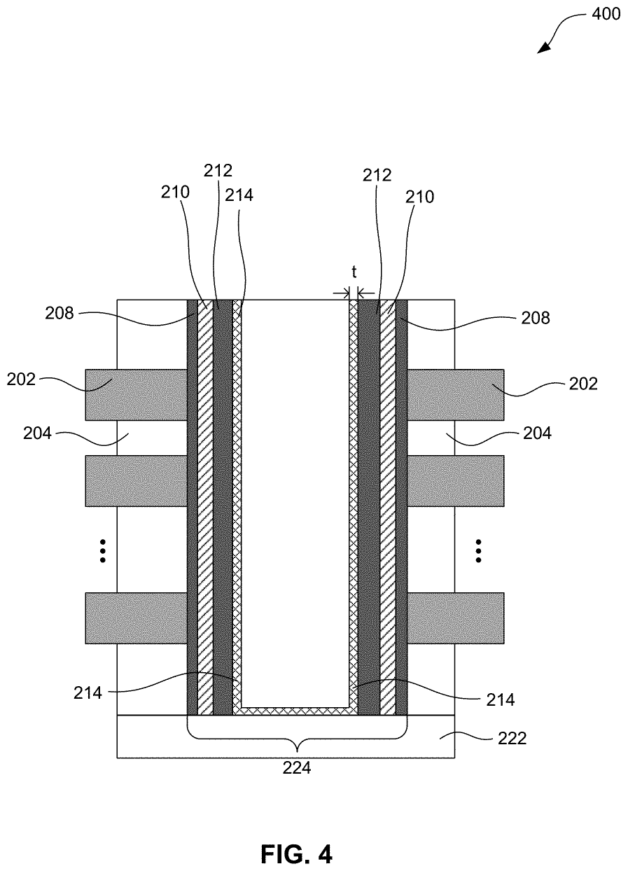

FIGS. 3 and 4 are cross-sectional views of a 3D NAND memory device that illustrate fabrications steps preceding to the formation of 3D NAND memory device 200 shown in FIG. 2.

FIG. 3 illustrates a blocking layer, a charge-trapping layer, and a tunneling layer are formed in openings of a 3D NAND memory device 300, according to some embodiments. In some embodiments, blocking layer 208, charge-trapping layer 210, and tunneling layer 212 shown in FIG. 3 can be collectively referred to as a composite dielectric layer. Substrate region 222 can be a region in the substrate that is doped using suitable doping processes such as ion implantation or diffusion. The alternating stack of a sacrificial layer, formed of silicon nitride, and insulating layer 204 are deposited over the substrate including substrate region 222 using similar techniques as forming layer 102 and 104, and is not described in detail here for simplicity. The sacrificial layer can be subsequently replaced by a conductive layer to form word lines. Hole 224 can be etched through the alternating stack of word line 202 and insulating layer 204 using one or more etching processes to expose a first portion of substrate region 222. For example, the etching process can include RIE processes. Blocking layer 208 can be deposited conformally over sidewalls of hole 224 and on a portion of substrate region 222. Charge-trapping layer 210 can be deposited conformally over an inner sidewall and horizontal surfaces of deposited blocking layer 208. In some embodiments, deposition techniques for layers 208, 210, and 212 can be similar as those for layers 108, 110 and 112. After the deposition of blocking layer 208, charge-trapping layer 210, and tunneling layer 212, an etching process can be used to remove portions of these layers that are formed on the top surface of substrate region 222 such that substrate region 222 is exposed at the bottom of hole 224. For example, a portion of substrate region 222 is exposed by etching blocking layer 208, charge-trapping layer 210, and tunneling layer 212 with an anisotropic etching process that has a greater etching rate in the vertical direction (e.g., along hole 224) that that of the lateral direction. In some embodiments, one or more etching processed can be used after the deposition of each layer of the composite dielectric layer.

FIG. 4 illustrates a channel layer formed in openings of a 3D NAND memory device 400, according to some embodiments. Channel layer 214 can be grown over a surface of tunneling layer 212 using suitable deposition techniques including, but not limiting to, CVD, ALD, PVD, and MOCVD. In some embodiments, channel layer 214 can be epitaxially grown. In some embodiments, channel layer 214 can also be doped during its growth (referred to as “in-situ doping”). Channel layer 214 can be formed of material that can provide improved carrier mobility (e.g., higher carrier mobility than doped silicon material.) For example, channel layer 214 can be formed using material that has direct band gap. In some embodiments, channel layer 214 can be formed of molybdenum disulfide, tungsten disulfide, molybdenum diselenide, any suitable two-dimensional material, and/or combinations thereof. In some embodiments, Channel layer 214 can have a thickness “t” measured in a lateral direction along the sidewalls of tunneling layer 212. In some embodiments, channel layer 214 can be a monolayer or include a plurality of monolayers of the two-dimensional material. For example, thickness t of channel layer 214 can be between about a monolayer of atoms and about 10 monolayers of atoms. For example, channel layer 214 can 5 monolayers of atoms. In some embodiments, channel layer 214 can include a bilayer structure. A lower thickness t of channel layer 214 can provide higher carrier mobility.

In some embodiments, insulating layer 220 is deposited over an inner surface of channel layer 214 and a semiconductor plug 230 can be formed on top surfaces of insulating layer 220 and channel layer 214. Insulating layer 220 and semiconductor plug 230 are not shown in FIG. 4 but shown in FIG. 2. Insulating layer 220 can be formed using any suitable insulating material, such as silicon oxide, silicon nitride, silicon oxynitride, silicon carbide, silicon oxycarbide, any suitable insulating material, and/or combinations thereof. In some embodiments, insulating layer 220 can be formed using a high-k dielectric material (e.g., dielectric material having dielectric constant greater than about 3.9). For example, insulating layer 220 can be formed using hafnium oxide. Insulating layer 220 can be formed using deposition processes such as CVD, PVD, ALD, any suitable deposition processes, and/or combinations thereof. In some embodiments, semiconductor plug can be formed using a deposition process similar to that of insulating layer 220.

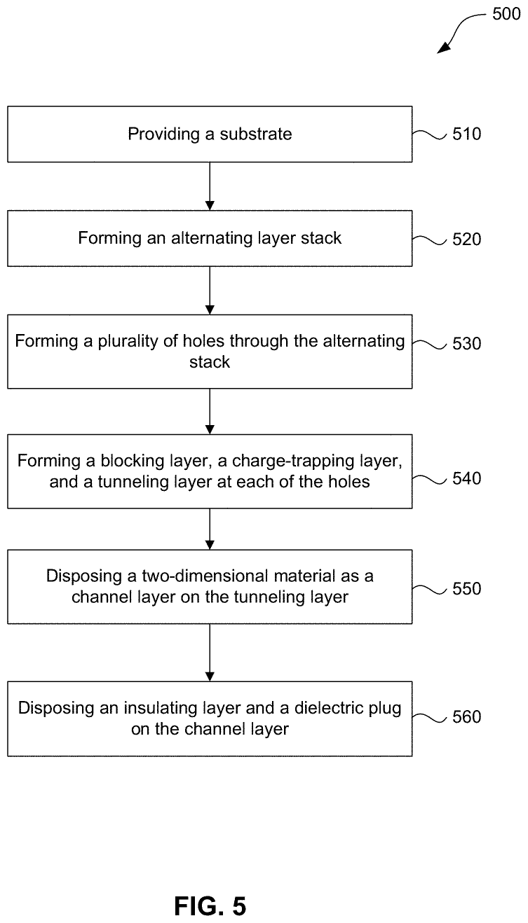

FIG. 5 is a flowchart of an exemplary method 500 for forming a 3D NAND memory device incorporating two-dimensional materials, according to some embodiments. The operations of method 500 can be used to form memory device structures illustrated in FIGS. 1-4. It should be understood that the operations shown in method 500 are not exhaustive and that other operations can be performed as well before, after, or between any of the illustrated operations. In some embodiments, some operations of exemplary method 500 can be omitted or include other operations that are not described here for simplicity. In some embodiments, operations of method 500 can be performed in a different order and/or vary.

In operation 510, a substrate is provided to from the memory device, according to some embodiments. The substrate can include any suitable material for forming the three-dimensional memory structure. For example, the substrate can include silicon, silicon germanium, silicon carbide, SOI, GOI, glass, gallium nitride, gallium arsenide, plastic sheet and/or other suitable III-V compound. In some embodiments, a doped region is formed over the substrate using photolithography processes and ion implantation or diffusion. An example of the substrate can be substrate region 222 as described above in FIG. 2.

In operation 520, an alternating layer stack is deposited over the substrate, according to some embodiments. In some embodiments, the alternating layer stack can include an alternating insulating/sacrificial layer stack. In some embodiments, the alternating layer stack can include an alternating insulating/conductor layer stack. The sacrificial layer of the alternating layer stack can include materials such as silicon nitride or other suitable materials. The insulating layer of the alternating layer stack can include materials such as silicon oxide or other suitable materials. The conductor layer of the alternating layer stack can include materials such as tungsten or other suitable materials. Each of the insulating, sacrificial, and conductor layers of the alternating layer stack can include materials deposited by one or more thin film deposition processes including, but not limiting to, CVD, PVD, ALD, or any combinations thereof. An example of the alternating layer stack can be alternating layers 202 and 204 as described above in FIG. 2.

In operation 530, a plurality of holes are etched through the alternating layer stack, according to some embodiments. Each hole of the plurality of holes can be etched through the alternating layer stack using one or more etching processes such as an RIE process. Additionally, the etching process can etch through at least a portion of the alternating layer stack. In some embodiments, the holes expose a first portion of the substrate. In some embodiments, the holes are located at the doped region of the substrate. An example of the hole can be hole 224 as described above in FIG. 2.

In operation 540, a composite dielectric layer including multiple layers is formed in each of the holes, according to some embodiments. The composite dielectric layer extends vertically through the alternating layer stack. The composite dielectric layer can be a combination of multiple dielectric layers including, but not limiting to, a tunneling layer, a charge-trapping layer, and a blocking layer. The tunneling layer can include any suitable dielectric materials such as, silicon oxide, silicon nitride, silicon oxynitride, or any combinations thereof. The charge-trapping layer can include any materials suitable for storing charge for memory operation. The blocking layer can include any suitable dielectric materials such as silicon oxide or a combination of silicon oxide/silicon nitride/silicon oxide (ONO). The blocking layer can further include a high-k dielectric layer. Each layer of the composite dielectric layer can be formed by processes such as ALD, CVD, PVD, any other suitable processes, or any combinations thereof. In some embodiments, the tunneling layer, the charge-trapping layer, and the blocking layer are ring-shaped (e.g., concentric rings) layers. For example, the tunneling layer is sequentially surrounded by the charge-trapping layer and the blocking layer. An outer surface of the blocking layer can be in contact with the alternating layer stack. An example of the composite dielectric layer can include blocking layer 208, charge-trapping layer 210, and tunneling layer 212, all described above in FIGS. 2-4.

In operation 550, a two-dimensional material is disposed as channel layer on the tunneling layer of the composited dielectric layer, according to some embodiments. The two-dimensional material can be a monolayer material that exhibits high carrier mobility and has a direct band gap. For example, the two-dimensional material can include molybdenum disulfide, tungsten disulfide, molybdenum diselenide, any suitable two-dimensional material, and/or combinations thereof. In some embodiments, channel layer formed using two-dimensional material can have a ring shape. For example, the channel layer can be sequentially surrounded by the tunneling layer, the charge-trapping layer, and the blocking layer. An example of the channel layer can be channel layer 214 described above in FIGS. 2-4.

In operation 560, an insulating layer and a dielectric plug are disposed on the channel layer, according to some embodiments. The insulating layer is in contact with an inner surface of the channel layer and can completely fill the remaining space of the hole that formed through the alternating dielectric layer stack. A dielectric plug can be formed on top surfaces of the channel layer and the composite dielectric layer. Example of the insulating layer and the dielectric plug can be insulating layer 220 and semiconductor plug 230 as described above in FIG. 2.

After operation 550, a memory string is formed within each of the holes. The memory string, including the channel layer and the composite dielectric layer, extends vertically above the substrate through the alternating layer stack. The channel layer can be formed using two-dimensional material such as molybdenum disulfide. The composite dielectric layer can include a tunneling layer, a charge-trapping layer, and a blocking layer. In addition, some dielectric layers of the alternating layer stack may be removed and replaced with conductor layers to form an alternating conductor/dielectric stack during, before, or after, operation 540-560. Each of the memory strings and the word lines (e.g., the conductor layers of the alternating conductor/dielectric stack) can form memory cells for storing data of 3D memory devices.

The present disclosure describes 3D NAND memory cells incorporating two-dimensional material as the channel material. The two-dimensional materials can provide improved carrier mobility which in turn improves the channel current density. In some embodiments, the two-dimensional material can include molybdenum disulfide, tungsten disulfide, molybdenum diselenide, any suitable two-dimensional material, and/or combinations thereof.

In some embodiments, a 3D NAND memory structure includes a substrate and a vertical insulating layer. The 3D NAND memory structure also includes a channel layer surrounding the vertical insulating layer. The channel layer is formed of a two-dimensional material. The 3D NAND memory structure further includes a plurality of vertical dielectric layers surrounding the channel layer and an alternating conductor/dielectric stack in contact with the plurality of vertical dielectric layers.

In some embodiments, a method for forming a 3D NAND memory string includes forming an alternating dielectric stack over a substrate and forming a hole through the alternating dielectric stack. The method also includes disposing a plurality of dielectric layers on sidewalls of the hole and disposing a channel layer in contact with the dielectric layers. The channel layer is formed using a two-dimensional material. The method also includes forming an insulating layer in physical contact with the channel layer.

In some embodiments, a 3D NAND memory device includes a substrate and a plurality of 3D NAND memory strings. Each of the 3D NAND memory strings includes a ring-shaped channel layer formed using a two-dimensional material. The 3D NAND memory device also includes a plurality of ring-shaped dielectric layers surrounding the ring-shaped channel layer and an alternating conductor/dielectric stack disposed on the substrate. Each conductor/dielectric stack of the alternating conductor/dielectric stack contacts a portion of the plurality of 3D NAND memory strings.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. A 3D NAND memory structure, comprising:
a substrate;
a vertical insulating layer;
a channel layer surrounding the vertical insulating layer, wherein the channel layer comprises a two-dimensional material;
a plurality of vertical dielectric layers surrounding the channel layer; and
an alternating conductor/dielectric stack in contact with the plurality of vertical dielectric layers.

2. The 3D NAND memory structure of claim 1, wherein the two-dimensional material comprises tungsten disulfide.

3. The 3D NAND memory structure of claim 1, wherein the two-dimensional material comprises molybdenum disulfide.

4. The 3D NAND memory structure of claim 1, wherein the plurality of vertical dielectric layers comprise a tunneling layer, a charge-trapping layer, and a blocking layer.

5. The 3D NAND memory structure of claim 4, wherein the tunneling layer surrounds the channel layer, the charge-trapping layer surrounds the tunneling layer, and the blocking layer surrounds the charge-trapping layer.

6. The 3D NAND memory structure of claim 4, wherein the tunneling layer comprise silicon oxide.

7. The 3D NAND memory structure of claim 4, wherein the charge-trapping layer comprise silicon nitride.

8. The 3D NAND memory structure of claim 4, wherein the blocking layer comprises silicon oxide or high-k material.

9. The 3D NAND memory structure of claim 1, wherein the two-dimensional material comprises molybdenum diselenide.

10. The 3D NAND memory structure of claim 1, wherein the channel layer comprises a monolayer of atoms.

11. A method for forming a 3D NAND memory string, comprising:
forming an alternating dielectric stack over a substrate;
forming a hole through the alternating dielectric stack;
disposing a plurality of dielectric layers on sidewalls of the hole;
disposing a channel layer in contact with the dielectric layers, wherein the channel layer comprises a two-dimensional material; and
forming an insulating layer in physical contact with the channel layer.

12. The method of claim 11, wherein the disposing the plurality of dielectric layers comprises depositing a tunneling layer, a charge-trapping layer, and a blocking layer.

13. A 3D NAND memory device, comprising:
a substrate;
a plurality of 3D NAND memory strings, wherein each of the 3D NAND memory strings comprises:
a ring-shaped channel layer comprising a two-dimensional material; and
a plurality of ring-shaped dielectric layers surrounding the ring-shaped channel layer; and
an alternating conductor/dielectric stack disposed on the substrate, wherein each conductor/dielectric stack of the alternating conductor/dielectric stack contacts a portion of the plurality of 3D NAND memory strings.

14. The 3D NAND memory device of claim 13, wherein each of the 3D NAND memory strings further comprises an insulating layer surrounded by the ring-shaped channel layer.

15. The 3D NAND memory device of claim 13, wherein each of the 3D NAND memory strings extend vertically above the substrate and through the alternating conductor/dielectric stack.

16. The 3D NAND memory device of claim 13, further comprising a semiconductor plug disposed over the ring-shaped channel layer.

17. The 3D NAND memory string of claim 13, wherein the two-dimensional material comprises molybdenum disulfide.

18. The 3D NAND memory device of claim 13, wherein the plurality of ring-shaped dielectric layers comprise a tunneling layer, a charge-trapping layer, and a blocking layer.

19. The 3D NAND memory device of claim 18, wherein the tunneling layer surrounds the ring-shaped channel layer, the charge-trapping layer surrounds the tunneling layer, and the blocking layer surrounds the charge-trapping layer.

20. The 3D NAND memory device of claim 13, wherein the two-dimensional material comprises a monolayer of atoms.
